(19) United States
(12) Patent Application Publication
(10) Pub. No.: US 2018/0277353 A1
(43) Pub. Date: Sep. 27, 2018

(54) SEMICONDUCTOR DEVICE AND SEMICONDUCTOR DEVICE MANUFACTURING METHOD

(71) Applicant: Renesas Electronics Corporation, Tokyo (JP)

(72) Inventor: Makoto NISHIDA, Hitachinaka-shi (JP)

(73) Assignee: Renesas Electronics Corporation, Tokyo (JP)

(21) Appl. No.: 15/906,033

(22) Filed: Feb. 27, 2018

(30) Foreign Application Priority Data
Mar. 22, 2017 (JP) 2017-055428

(51) Int. Cl. H01L 21/02; H01L 29/78; H01L 29/66; H01L 27/088

(52) U.S. Cl. CPC H01L 21/0206; H01L 29/7833; H01L 21/76202; H01L 27/088; H01L 29/6659

(57) ABSTRACT

A semiconductor device manufacturing method according to one embodiment includes the steps of: forming a gate insulator on a surface of a semiconductor substrate; forming at least one semiconductor element on the surface of the semiconductor substrate, the semiconductor element including a source region, a drain region, and a gate electrode; forming a first film on the surface of the semiconductor substrate; and cleaning the semiconductor substrate with an acid solution. The first film is made of a material that is oppositely charged with respect to a material constituting the semiconductor substrate in the acid solution. The first film is formed so as to be located in an inactive region that does not overlap a portion in which the source region is formed, a portion in which the drain region is formed, and a portion in which the gate electrode is formed in plan view.

This nonprovisional application is based on Japanese Patent Application No. 2017-055428 filed on Mar. 22, 2017 with the Japan Patent Office, the entire contents of which are hereby incorporated by reference.

### BACKGROUND OF THE INVENTION

### Field of the Invention

The present invention relates to a semiconductor device and a semiconductor device manufacturing method.

### Description of the Background Art

Conventionally, a semiconductor device manufacturing method described in Japanese Patent Laying-Open No. 2000-156380 (Patent Document 1) is known. The semiconductor device manufacturing method described in Patent Document 1 includes a process of forming a trap pattern in which a trap for accommodating a foreign matter that could adhere to a circuit pattern is provided and a process of cleaning a semiconductor wafer using a cleaning solution such that the cleaning solution flows into the trap.

An electrical short circuit between structures constituting a circuit pattern due to the foreign matter adhering to the circuit pattern can be prevented according to the semiconductor device manufacturing method described in Patent Document 1.

### SUMMARY OF THE INVENTION

In the semiconductor device manufacturing method described in Patent Document 1, the trap pattern for accommodating the foreign matter needs to be thick. Therefore, in the semiconductor device manufacturing method described in Patent Document 1, it is necessary to consider an influence of a step due to a thickness of the trap pattern in a process after the trap pattern is formed.

Other problems and novel features will be apparent from the description of the specification and the accompanying drawings.

A semiconductor device manufacturing method according to one embodiment includes the steps of: forming a gate insulator on a surface of a semiconductor substrate; forming at least one semiconductor element on the surface of the semiconductor substrate, the semiconductor element including a source region, a drain region, and a gate electrode that faces a portion of the semiconductor substrate with the gate insulator interposed therebetween, the portion sandwiched between the source region and the drain region; forming a first film on the surface of the semiconductor substrate; and cleaning the semiconductor substrate with an acid solution. The first film is made of a material that is oppositely charged with respect to a material constituting the semiconductor substrate in the acid solution. The step of forming the first film is performed before the step of forming the gate insulator. The first film is formed so as to be located in an inactive region that does not overlap a portion in which the source region is formed, a portion in which the drain region is formed, and a portion in which the gate electrode is formed in plan view.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an enlarged plan view of a semiconductor device according to a first embodiment.

FIG. 2 is a general plan view of the semiconductor device of the first embodiment.

FIG. 3 is a sectional view of the semiconductor device of the first embodiment.

FIG. 4 is a process chart illustrating a method for manufacturing the semiconductor device of the first embodiment.

FIG. 5 is a sectional view of the semiconductor device of the first embodiment after an element isolation film forming process.

FIG. 6 is a sectional view of the semiconductor device of the first embodiment after a first film forming process.

FIG. 7 is a sectional view of the semiconductor device of the first embodiment after a cleaning process.

FIG. 8 is a sectional view of the semiconductor device of the first embodiment after a gate insulator forming process.

FIG. 9 is a sectional view of the semiconductor device of the first embodiment after a gate electrode forming process.

FIG. 10 is a sectional view of the semiconductor device of the first embodiment after a first impurity implantation process.

FIG. 11 is a sectional view of the semiconductor device of the first embodiment after a sidewall spacer forming process.

FIG. 12 is a sectional view of the semiconductor device of the first embodiment after a second impurity implantation process.

FIG. 13 is a sectional view of the semiconductor device of the first embodiment after a pre-metal insulator forming process.

FIG. 14 is a sectional view of the semiconductor device of the first embodiment after a contact plug forming process.

FIG. 15 is a sectional view of the semiconductor device of the first embodiment after a first wiring layer forming process.

FIG. 16 is a sectional view of the semiconductor device of the first embodiment after an interlayer insulator forming process.

FIG. 17 is a sectional view of the semiconductor device of the first embodiment after a via plug forming process.

FIG. 18 is a sectional view of a semiconductor device according to a second embodiment.

FIG. 19 is a process chart illustrating a method for manufacturing the semiconductor device of the second embodiment.

FIG. 20 is a sectional view of the semiconductor device of the second embodiment after the first film forming process.

FIG. 21 is a sectional view of the semiconductor device of the second embodiment after the element isolation film forming process.

FIG. 22 is a sectional view of a semiconductor device according to a third embodiment.

FIG. 23 is a process chart illustrating a method of manufacturing the semiconductor device of the third embodiment.

FIG. 24 is a sectional view of the semiconductor device of the third embodiment after the second film forming process and the sidewall spacer forming process.

FIG. 25 is a sectional view of a semiconductor device according to a fourth embodiment.

FIG. 26 is a process chart illustrating a method of manufacturing the semiconductor device of the fourth embodiment.

FIG. 27 is a sectional view of the semiconductor device of the fourth embodiment after the first film forming process.

### DESCRIPTION OF THE PREFERRED EMBODIMENTS

Hereinafter, embodiments will be described with reference to the drawings. In the following drawings, the same or corresponding component is designated by the same reference numeral, and the overlapping description will be omitted.

### First Embodiment

A configuration of a semiconductor device according to a first embodiment will be described below.

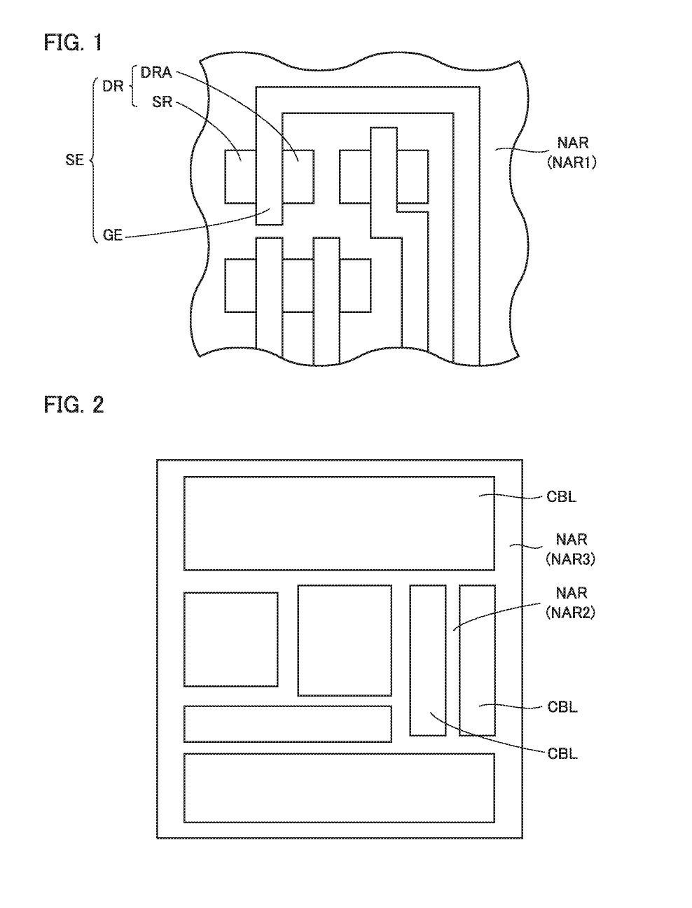

As illustrated in FIGS. 1 to 3, the semiconductor device of the first embodiment includes a semiconductor substrate SUB, a gate insulator GO, a gate electrode GE, a first film FL, an element isolation film ISL, a sidewall spacer SWS, a pre-metal insulator PMD, a contact plug CP, a wiring layer WL1, an interlayer insulator ILD, a via plug VP, and a wiring layer WL2.

In FIG. 1, to clarify configurations of semiconductor substrate SUB and gate electrode GE, configurations of other components except for semiconductor substrate SUB and gate electrode GE are omitted.

Semiconductor substrate SUB includes a first surface FS (front surface) and a second surface SS (rear surface). Second surface SS is a surface opposite to first surface FS. For example, semiconductor substrate SUB is made of single-crystal silicon (Si). Semiconductor substrate SUB includes an impurity diffusion region DR. Impurity diffusion region DR includes a source region SR and a drain region DRA. Source region SR and drain region DRA are disposed while being in contact with first surface FS. Source region SR is disposed while separated from drain region DRA. Semiconductor substrate SUB includes a portion sandwiched between source region SR and drain region DRA.

A conductivity type in source region SR and drain region DRA is a first conductivity type. A conductivity type in the portion of semiconductor substrate SUB sandwiched between the source portion and drain region DRA is a second conductivity type. The second conductivity type is the opposite conductivity type to the first conductivity type. For example, when the first conductivity type is an n type, the second conductivity type is a p type.

Source region SR includes a first portion SR1 and a second portion SR2. Drain region DRA includes a first portion DRA1 and a second portion DRA2. First portion SR1 is disposed below a sidewall spacer SWS (to be described later). First portion DRA1 is disposed below sidewall spacer SWS (to be described later).

An impurity concentration of first portion SR1 is lower than that of second portion SR2. First portion DRA1 has an impurity concentration lower than that of second portion DRA2. That is, first portion SR1 and first portion DRA1 form a Lightly Doped Diffusion (LDD) structure.

Gate insulator GO is disposed on first surface FS of semiconductor substrate SUB. More specifically, gate insulator GO is disposed on a portion of first surface FS sandwiched between source region SR and drain region DRA. For example, gate insulator GO is made of silicon dioxide (SiO₂).

Gate electrode GE is disposed on gate insulator GO. Consequently, gate electrode GE faces the portion of semiconductor substrate SUB sandwiched between source region SR and drain region DRA while being insulated from the portion. That is, gate electrode GE faces the portion of semiconductor substrate SUB sandwiched between source region SR and drain region DRA with gate insulator GO interposed therebetween. For example, gate electrode GE is made of impurity-doped polycrystalline Si.

A semiconductor element SE is constructed with source region SR, drain region DRA, and gate electrode GE. Preferably the number of semiconductor elements SE is plural.

The semiconductor device of the first embodiment includes an element block CBL. Preferably the number of element blocks CBL is plural. Element blocks CBL are disposed while separated from each other in plan view. That is, each of element blocks CBL is surrounded by a region where semiconductor element SE is not provided (for example, a region where element isolation film ISL is provided) in plan view, and a width of the region is larger than an interval between semiconductor elements SE, which are disposed adjacent to each other in element block CBL. Each of element blocks CBL is constructed with the plurality of semiconductor elements SE. Semiconductor elements SE each of which constitutes element block CBL are electrically connected to each other, and act as an electric circuit. The plan view means the case that first surface FS is viewed in a direction orthogonal to first surface FS.

As described above, element block CBL is surrounded by the region where semiconductor element SE is not formed. Consequently, semiconductor element SE is not formed between element blocks CBL. Further, semiconductor element SE is not formed outside element block CBL located on an outermost side in plan view.

First film FL is disposed on first surface FS. The case that first film FL is disposed on first surface FS includes the case that first film FL is in contact with first surface FS and the case that first film FL is not in contact with first surface FS. That is, first film FL may be disposed on element isolation film ISL (to be described later).

First film FL is disposed in an inactive region NAR. Inactive region NAR is a region that does not overlap the portion where source region SR, drain region DRA, and gate electrode GE are formed in plan view. That is, inactive region NAR is a region located around the portion where source region SR and drain region DRA are formed in plan view, and located around the portion where gate electrode GE is formed in plan view. The term “first film FL is disposed in inactive region NAR” means that first film FL is located inside an end of inactive region NAR in plan view.

Inactive region NAR exists inside each element block CBL in plan view. Hereinafter, inactive region NAR existing inside each element block CBL in plan view is referred to as a first region NAR1.

As described above, semiconductor element SE is not formed between element blocks CBL. Therefore, inactive region NAR also exists between element blocks CBL adjacent to each other in plan view. Hereinafter, inactive region NAR existing between element blocks CBL adjacent in plan view is referred to as a second region NAR2.

As described above, semiconductor element SE is not formed outside element block CBL located at the outermost position in plan view. Consequently, inactive region NAR also exists further outside element block CBL disposed on the outermost side in plan view. Hereinafter, inactive region NAR existing outside element block CBL positioned on the outermost side in plan view is referred to as a third region NAR3.

First film FL may be located in first region NAR1. First film FL may be located in third region NAR3. In other words, first film FL needs to be located inside at least one of first region NAR1, second region NAR2, and third region NAR3.

Preferably a thickness of first film FL ranges from 50 nm to 200 nm. Preferably a total area of first film FL in plan view is greater than or equal to 10 μm². For example, first film FL is made of silicon nitride (SiN).

First film FL is made of a material that is oppositely charged with respect to the material constituting semiconductor substrate SUB in an acid solution. That is, first film FL is made of such a material that has a zeta potential opposite in sign to that of the material constituting semiconductor substrate SUB in the acid solution. Preferably first film FL is made of a material that is oppositely charged with respect to the material constituting semiconductor substrate SUB in the acid solution having a pH of 4 or less. More preferably first film FL is made of the material that is oppositely charged with respect to the material constituting semiconductor substrate SUB in the acid solution having a pH of 3 or less.

For example, in the case that Si is the material constituting semiconductor substrate SUB and that SiN is the material constituting first film FL, in the acid solution having a pH of 4 or less, the material constituting semiconductor substrate SUB is negatively charged and the material constituting first film FL is positively charged. An example of the acid solution having a pH of 4 or less is sulfuric acid hydrogen peroxide mixture liquid (SPM).

Element isolation film ISL is disposed on first surface FS. Element isolation film ISL, surrounds a portion of first surface FS in which impurity diffusion region DR is formed (a portion of first surface FS in which source region SR and drain region DRA are formed). Element isolation film ISL is constructed with an insulator. Element isolation film ISL insulates and separates semiconductor element SE. Element isolation film ISL may be Local Oxidation Of Silicon (LOCOS). Element isolation film ISL may be Shallow Trench Isolation (STI). For example, element isolation film ISL is made of SiO₂.

Sidewall spacer SWS is disposed on gate insulator GO. Sidewall spacer SWS is disposed beside gate electrode GE. Sidewall spacer SWS is disposed on source region SR and drain region DRA, which are located on the side of gate electrode GE. For example, sidewall spacer SWS is made of SiO₂ or SiN.

Pre-metal insulator PMD is disposed on first surface FS of semiconductor substrate SUB. More specifically pre-metal insulator PMD is disposed so as to cover gate electrode GE, sidewall spacer SWS, and first film FL. For example, pre-metal insulator PMD is made of SiO₂.

Contact plug CP is disposed in pre-metal insulator PMD. More specifically contact plug CP is disposed in a contact hole CH made in pre-metal insulator PMD. Contact plug CP is electrically connected to source region SR, drain region DRA, and gate electrode GE. For example, contact plug CP is made of tungsten (W).

Wiring layer WL1 is disposed on pre-metal insulator PMD. Wiring layer WL1 is electrically connected to contact plug CP. For example, wiring layer WL1 is made of aluminum (Al), an Al alloy, copper (Cu), or a Cu alloy.

Interlayer insulator ILD is disposed so as to cover wiring layer WL1 on pre-metal insulator PMD. For example, interlayer insulator ILD is made of SiO₂. Via plug VP is disposed in interlayer insulator ILD. More specifically via plug VP is disposed in a via hole VH made in interlayer insulator ILD. Via plug VP is electrically connected to wiring layer WL1. For example, via plug VP is made of W.

Wiring layer WL2 is disposed on interlayer insulator ILD. Wiring layer WL2 is electrically connected to via plug VP. For example, wiring layer WL2 is made of Al, an Al alloy, Cu, or a Cu alloy.

Although the two wiring layers are described above, the semiconductor device of the first embodiment may have a structure in which, while an interlayer insulator and a wiring layer are laminated on wiring layer WL2, more wiring layers are formed by electrically connecting the wiring layers with a via plug.

A method for manufacturing the semiconductor device of the first embodiment will be described below.

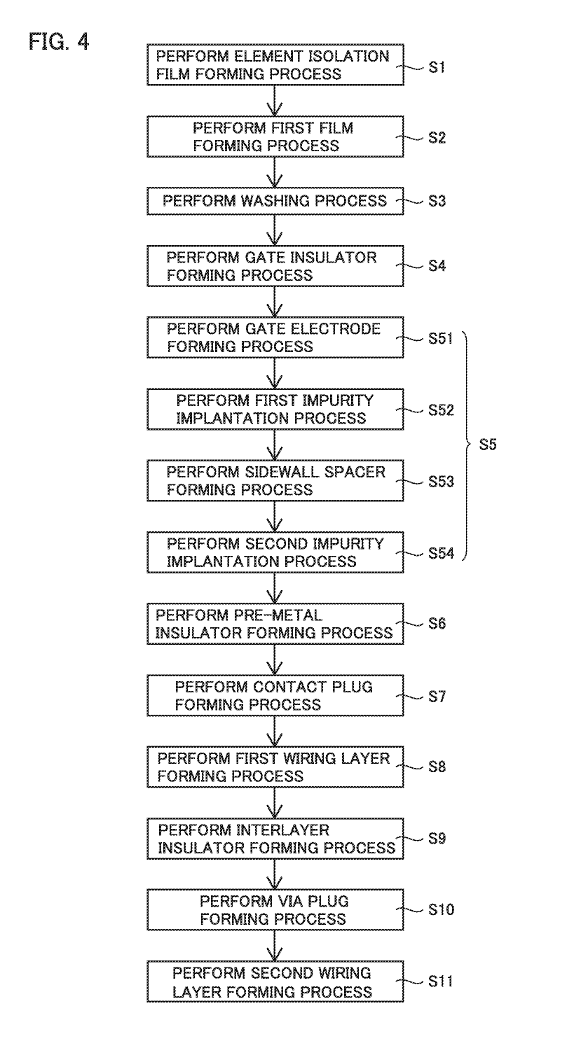

As illustrated in FIG. 4, the method of manufacturing the semiconductor device of the first embodiment includes an element isolation film forming process S1, a first film forming process S2, a cleaning process S3, a gate insulator forming process S4, a semiconductor element forming process S5, a pre-metal insulator forming process S6, a contact plug forming process S7, a first wiring layer forming process S8, an interlayer insulator forming process S9, a via plug forming process S10, and a second wiring layer forming process S11.

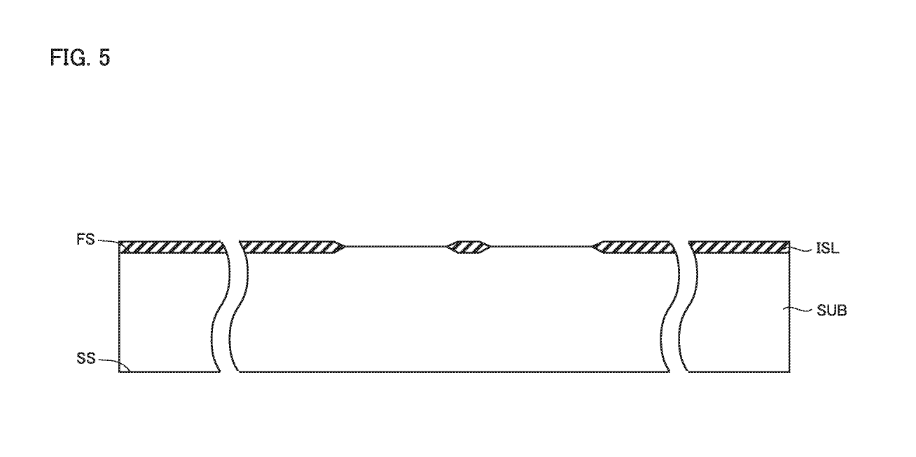

As illustrated in FIG. 5, in element isolation film forming process S1, element isolation film ISL is formed on first surface FS of semiconductor substrate SUB so as to surround the part in which impurity diffusion region DR is formed. In the formation of element isolation film ISL, first, a mask is formed on first surface FS of semiconductor substrate SUB. The mask is disposed on first surface FS located at the portion in which impurity diffusion region DR is formed. For example, the mask is constructed with a SiO₂ film and a SiN film laminated on the SiO₂ film.

In the formation of element isolation film ISL, second, thermal oxidation of first surface FS of semiconductor substrate SUB is performed. The thermal oxidation is not performed in the portion of first surface FS in which the mask is disposed. As a result, element isolation film ISL is formed only on the portion of first surface FS in which the mask is not disposed (that is, the portion of first surface FS surrounding the portion in which impurity diffusion region DR is formed).

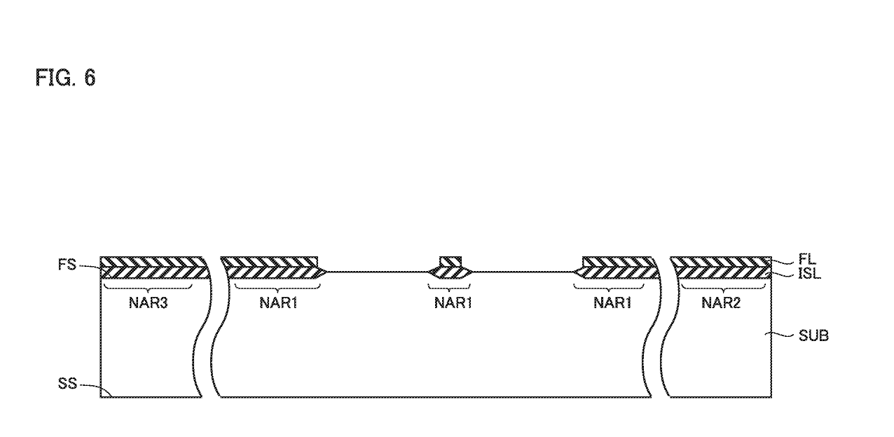

As illustrated in FIG. 6, in first film forming process S2, first film FL is formed on first surface FS located in inactive region NAR. In first film forming process S2, first, the material constituting first film FL is deposited on first surface FS by Chemical Vapor Deposition (CVD) or the like.

In first film forming process S2, second, the material constituting deposited first film FL is patterned, For example, the material constituting deposited first film FL is patterned by photolithography. The patterning is performed such that the material constituting first film FL deposited on first surface FS located outside inactive region NAR is removed, and such that the material constituting first film FL deposited on first surface FS located in inactive region NAR is left. As a result, first film FL is formed on inactive region NAR.

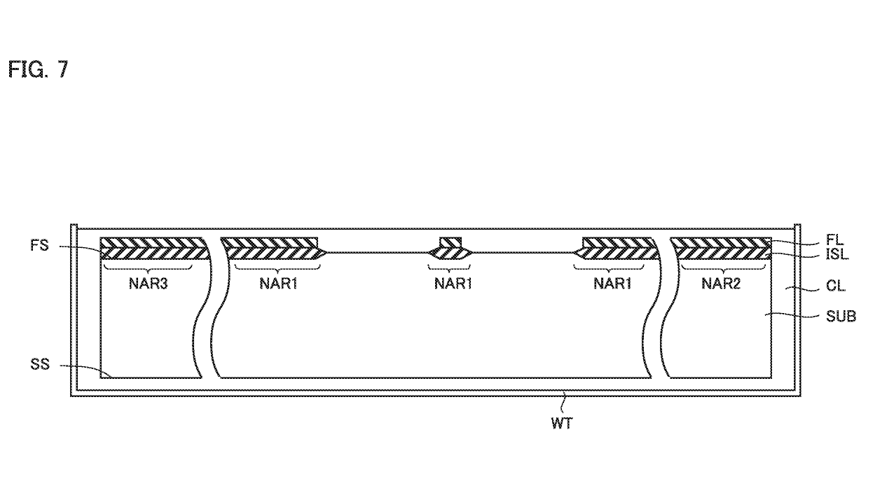

Semiconductor substrate SUB on which first film FL and element isolation film ISL are formed is cleaned in cleaning process S3 as illustrated in FIG. 7. The cleaning is performed by immersing semiconductor substrate SUB in which first film FL and element isolation film ISL are formed in a cleaning tank WT containing a cleaning solution CL. Cleaning solution CL is an acidic solution such as sulfuric acid hydrogen peroxide mixture liquid.

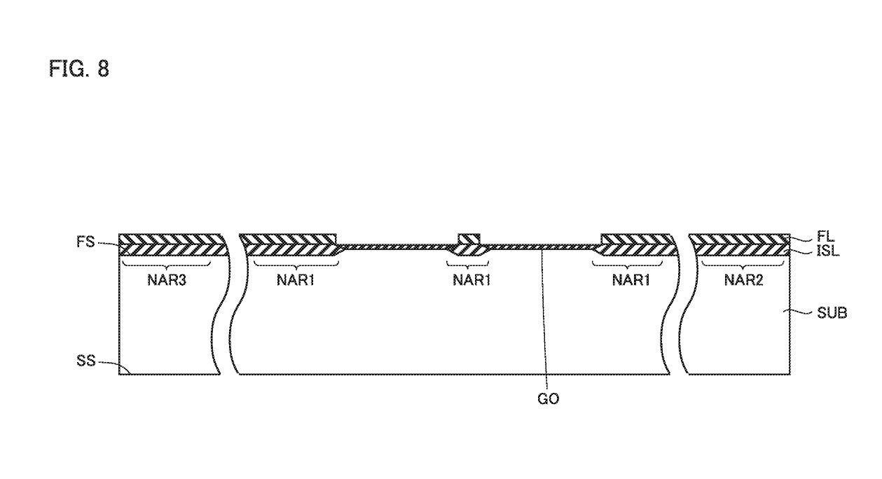

Gate insulator GO is formed in gate insulator forming process S4 as illustrated in FIG. 8. Gate insulator GO is formed by thermally oxidizing first surface FS (first surface FS of semiconductor substrate SUB located outside inactive region NAR) of semiconductor substrate SUB exposed from first film FL and element isolation film ISL.

Semiconductor element forming process S5 includes a gate electrode forming process S51, a first impurity implantation process S52, a sidewall spacer forming process S53, and a second impurity implantation process S54.

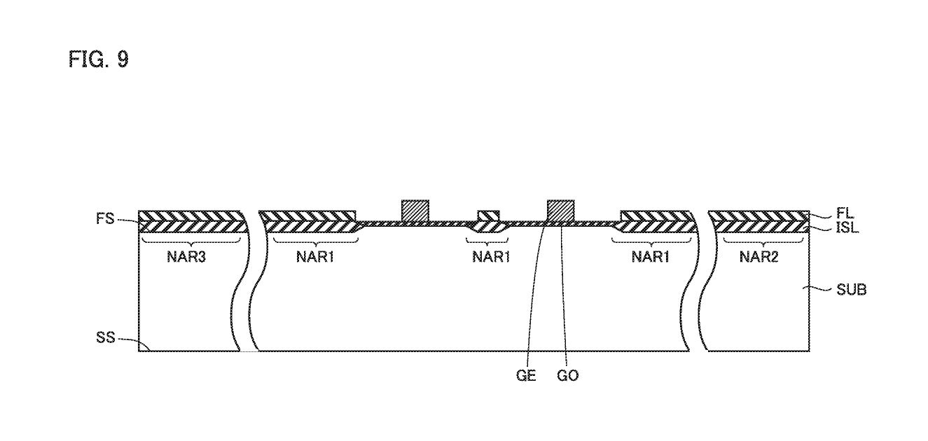

As illustrated in FIG. 9, in gate electrode forming process Se, gate electrode GE is formed on gate insulator GO formed in the portion of semiconductor substrate SUB sandwiched between the portion in which source region SR is formed and the portion in which drain region DRA is formed. Gate electrode GE is formed by depositing the material constituting gate electrode GE by CVD or the like and by patterning the material constituting deposited gate electrode GE by photolithography.

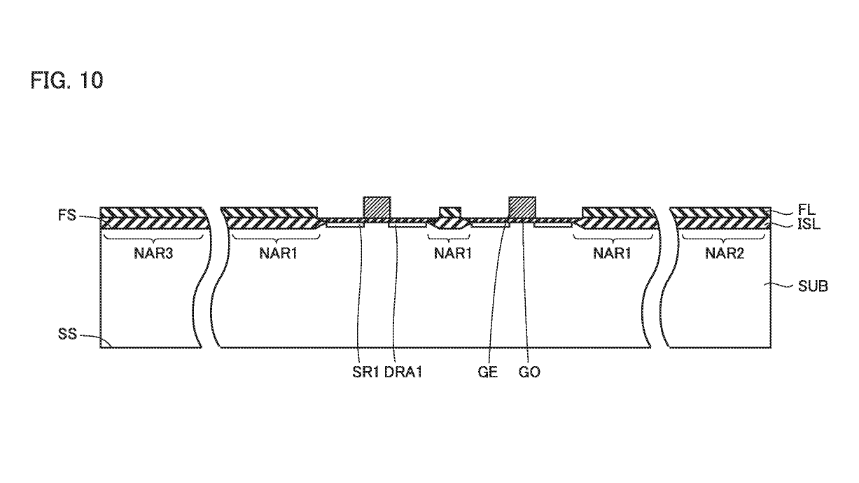

First portion SR1 and first portion DRA1 are formed in first impurity implantation process S52 as illustrated in FIG. 10. First portion SR1 and first portion DRA1 are formed by performing ion implantation with gate electrode GE, first film FL, and element isolation film ISL as a mask.

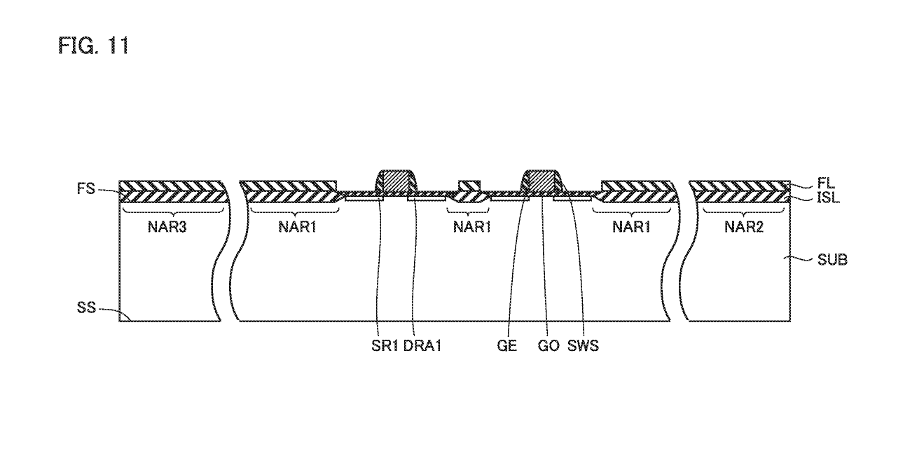

As illustrated in FIG. 11, in sidewall spacer forming process S53, sidewall spacer SWS is formed on the lateral side of gate electrode GE. In the formation of sidewall spacer SWS, first, the material constituting sidewall spacer SWS is formed on gate electrode GE, gate insulator GO and first film FL by CVD or the like. In the formation of sidewall spacer SWS, second, anisotropic etching such as Reactive Ion Etching (RIE) is performed on the material constituting deposited sidewall spacer SWS. The anisotropic etching is performed until an upper surface of gate electrode GE is exposed.

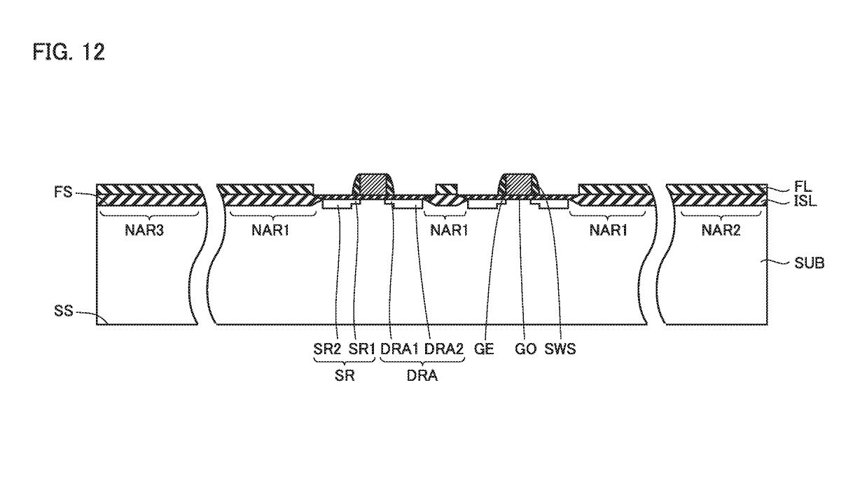

Second portion SR2 and second portion DRA2 are formed in second impurity implantation process S54 as illustrated in FIG. 12. Second portion SR2 and second portion DRA2 are formed by performing ion implantation with gate electrode GE, sidewall spacer SWS, first film FL, and element isolation film ISL as a mask.

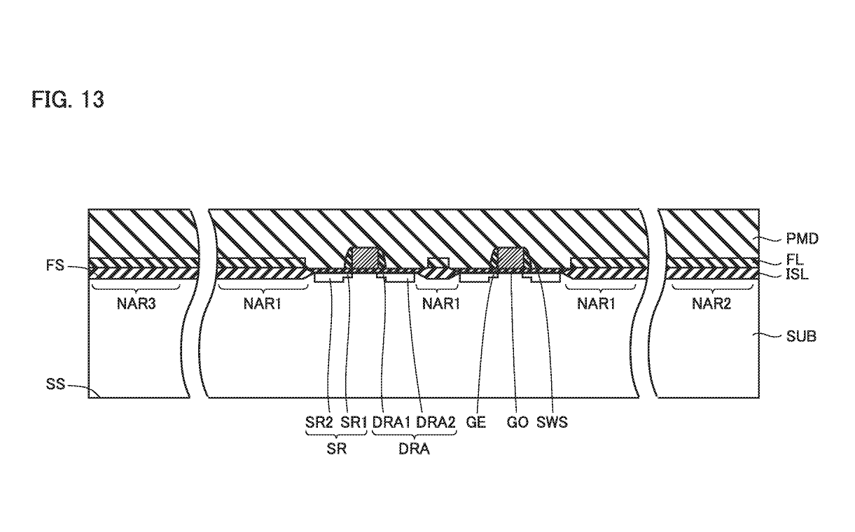

As illustrated in FIG. 13, in pre-metal insulator forming process S6, pre-metal insulator PMD is formed on first surface FS of semiconductor substrate SUB. In the formation of pre-metal insulator PMD, first, the material forming pre-metal insulator PMD is formed by CVD or the like. In the formation of pre-metal insulator PMD, second, planarization of the upper surface of deposited pre-metal insulator PMD is performed by Chemical Mechanical Polishing (CMP) or the like.

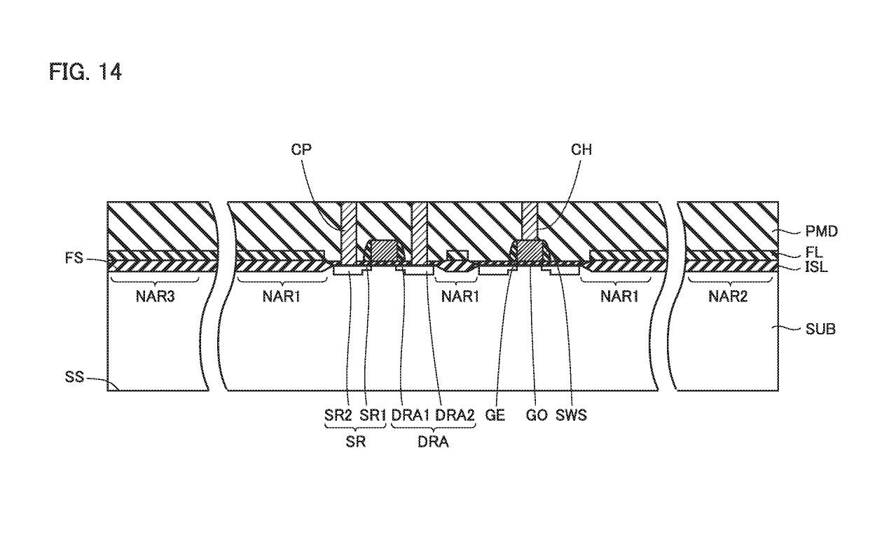

As illustrated in FIG. 14, in contact plug forming process S7, contact plug CP is formed in pre-metal insulator PMD. In contact plug forming process S7, first, contact hole CH is made in pre-metal insulator PMD. Contact hole CH is made by the anisotropic etching such as RIE.

In contact plug forming process S7, second, contact hole CH is filled with the material constituting contact plug CP. For example, contact hole CH is filled with the material constituting contact plug CP by CVD or the like. Third, the material constituting contact plug CP, which protrudes from contact hole CH, is removed in contact plug forming process S7. For example, the material constituting contact plug CP, which protrudes from contact hole CH, is removed by CMP.

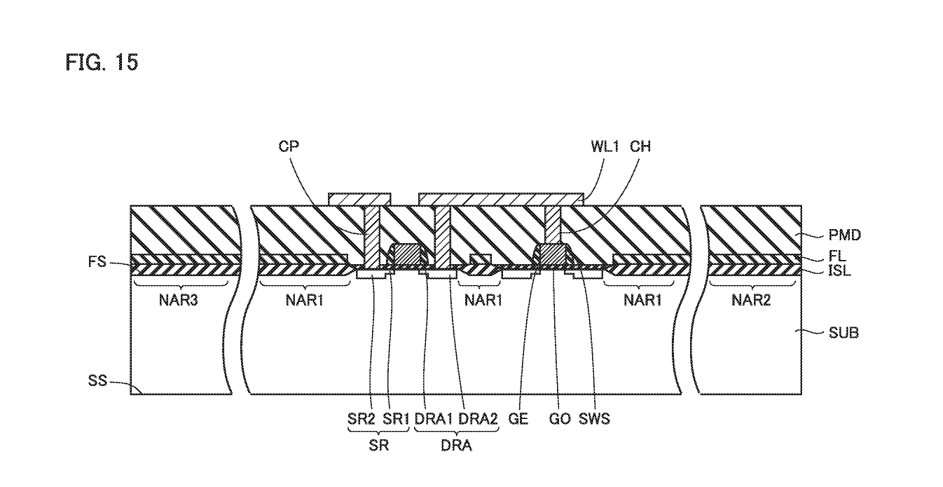

As illustrated in FIG. 15, in first wiring layer forming process S8, wiring layer WL1 is formed on pre-metal insulator PMD. Wiring layer WL1 is formed by depositing the material constituting wiring layer WL1 by sputtering or the like, and by patterning the material constituting deposited wiring layer WL1 by photolithography or the like.

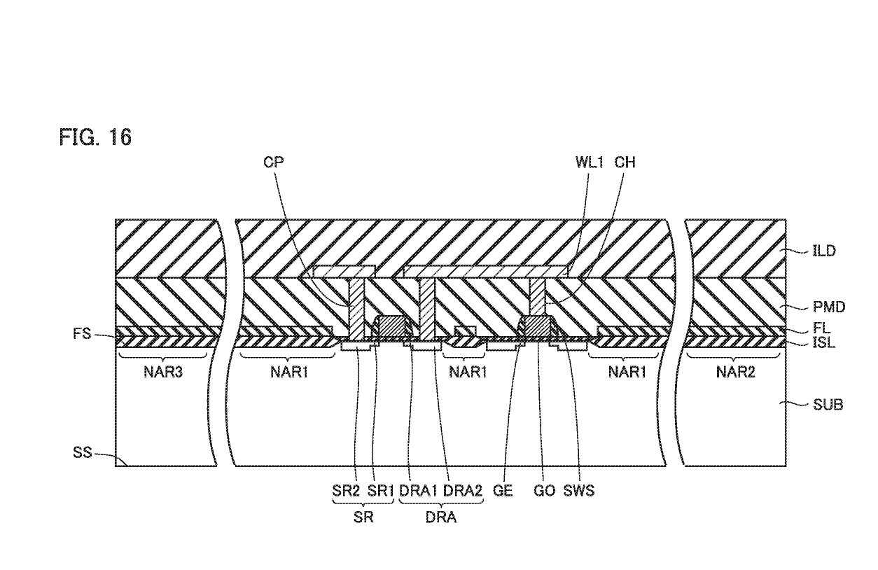

As illustrated in FIG. 16, in interlayer insulator forming process S9, interlayer insulator ILD is formed on pre-metal insulator PMD and wiring layer WL1. Interlayer insulator ILD is formed by depositing the material constituting interlayer insulator ILD by CVD or the like, and by planarizing the upper surface of the material constituting deposited interlayer insulator ILD by CMP or the like.

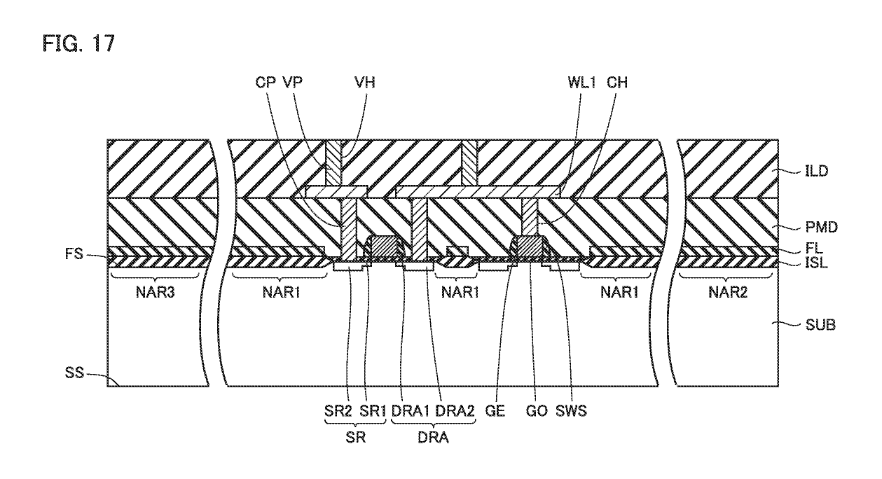

As illustrated in FIG. 17, in via plug forming process S10, via plug VP is formed in interlayer insulator MD. In via plug forming process S10, first, via hole VH is made in interlayer insulator ILD. For example, via hole VH is made by the anisotropic etching such as RM. In via plug forming process S10, second, via hole VH is filled with the material constituting via plug VP. For example, via hole VH is filled with the material constituting the via plug by CVD or the like. Third, the material constituting via plug VP, which protrudes from via hole VH, is removed. For example, the material constituting via plug VP, which protrudes from via hole VH, is removed by CMP.

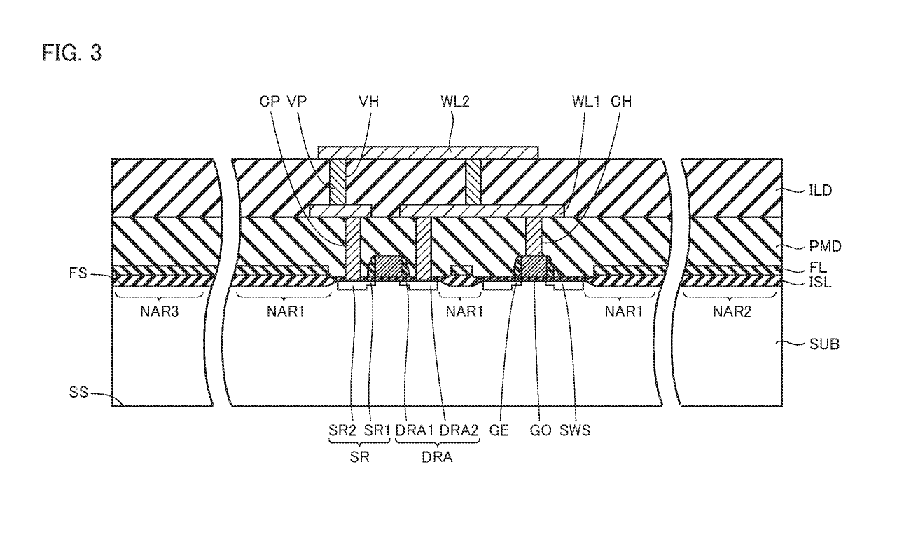

In second wiring layer forming process S11, wiring layer WL2 is formed on interlayer insulator ILD. Wiring layer WL2 is formed by depositing the material forming wiring layer WL2 by sputtering or the like, and by patterning the material constituting deposited wiring layer WL2 by photolithography or the like. Consequently, the structure of the semiconductor device of the first embodiment in FIG. 3 is formed.

The semiconductor device of the first embodiment having more wiring layers is manufactured by further repeating interlayer insulator forming process S9, via plug forming process S10, and second wiring layer forming process S11. The film disposed below sidewall spacer SWS is not limited to gate insulator GO, but a film newly formed by the thermal oxidation or CVD before first portion SR1 and first portion DRA1 are formed in first impurity implantation process S52 may be disposed.

Effects of the semiconductor device and the method of manufacturing the semiconductor device of the first embodiment will be described below.

When a foreign matter adheres to first surface FS of semiconductor substrate SUB located at the portion in which semiconductor element SE is formed in performing gate insulator forming process S4, there is a possibility that semiconductor element SE is defective. Consequently, cleaning process S3 is performed immediately before gate insulator forming process S4 is performed.

The foreign matter is detached from the surface of semiconductor substrate SUB into cleaning solution CL by immersing semiconductor substrate SUB in cleaning solution CL. However, sometimes the foreign matter detached into cleaning solution CL adheres to the surface of semiconductor substrate SUB again when semiconductor substrate SUB is taken out from cleaning solution CL.

In the method for manufacturing the semiconductor device of the first embodiment, first film forming process S2 is performed before gate insulator forming process S4. The material constituting first film FL is oppositely charged with respect to the material constituting semiconductor substrate SUB in cleaning solution CL that is the acid solution. The foreign matter adhering to the surface of semiconductor substrate SUB contains the material constituting semiconductor substrate SUB. For this reason, the foreign matter detached from the surface of semiconductor substrate SUB into cleaning solution CL is adsorbed by first film FL by electrostatic attractive force between the foreign matter and first film FL. As a result, in taking out semiconductor substrate SUB from cleaning solution CL, it is difficult for the foreign matter to adhere to the surface of semiconductor substrate SUB again.

As described above, first film FL does not trap the foreign matter due to a physical structure of first film FL, but traps the foreign matter by the electrostatic attractive force between the foreign matter and first film FL in the acid solution. Consequently, it is not necessary to form thick first film FL. As described above, in the semiconductor device and the method of manufacturing the semiconductor device of the first embodiment, occurrence of the defect in semiconductor element SE can be prevented while occurrence of a step due to the structure that traps the foreign matter is prevented.

In the semiconductor device of the first embodiment, in the case that first film FL is disposed on first surface FS located in first region NAR1, first film FL is disposed close to the portion in which semiconductor element SE is formed. Consequently, in this case, it is difficult for the foreign matter in cleaning solution CL to further re-adhere to the portion in which semiconductor element SE is formed, and the occurrence of defect of semiconductor element SE can further be prevented.

Semiconductor element SE is not formed on first surface FS located in second region NAR2 and third region NAR3. Consequently, even if the step occurs in second region NAR2 and third region NAR3 as first film FL is formed, the step has a little influence on the formation of semiconductor element SE. Therefore, in this case, the influence of the step due to the formation of first film FL can further be prevented.

### Second Embodiment

A configuration of a semiconductor device according to a second embodiment will be described below. In the following description, a point different from the configuration of the semiconductor device of the first embodiment will be mainly described, and the same description will be omitted.

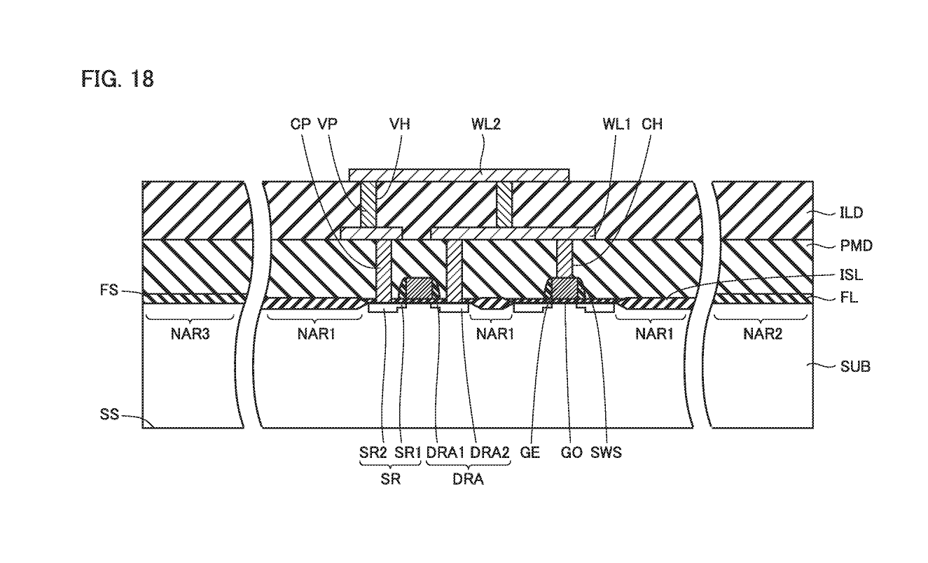

As illustrated in FIG. 18, the semiconductor device of the second embodiment includes semiconductor substrate SUB, gate insulator GO, gate electrode GE, first film FL, element isolation film ISL, sidewall spacer SWS, pre-metal insulator PMD, contact plug CP, wiring layer WL1, interlayer insulator ILD, via plug VP, and wiring layer WL2.

Semiconductor substrate SUB includes first surface FS and second surface SS. Inactive region NAR includes first region NAR1, second region NAR2, and third region NAR3.

Semiconductor substrate SUB includes an impurity diffusion region DR. Impurity diffusion region DR includes a source region SR and a drain region DRA. Source region SR includes a first portion SR1 and a second portion SR2. Drain region DRA includes first portion DRA1 and second portion DRA2.

Source region SR, drain region DRA, gate insulator GO, and gate electrode GE constitute semiconductor element SE. The plurality of semiconductor elements SE are provided. The plurality of semiconductor elements SE constitute the plurality of element blocks CBL. In these respects, the semiconductor device of the second embodiment is the same as the semiconductor device of the first embodiment.

The semiconductor device of the second embodiment is different from the semiconductor device of the first embodiment in the disposition of first film FL and element isolation film ISL.

First film FL is disposed while being in contact with first surface FS of semiconductor substrate SUB. More specifically, first film FL is disposed while being in contact with first surface FS located in second region NAR2 and third region NAR3. Element isolation film ISL is disposed on first surface FS located outside second region NAR2 and third region NAR3. That is, first film FL and element isolation film ISL are arranged so as not to overlap with each other in plan view.

A method of manufacturing the semiconductor device of the second embodiment will be described below. In the following description, a point different from the method of manufacturing the semiconductor device of the first embodiment will mainly be described, and the overlapping description will be omitted.

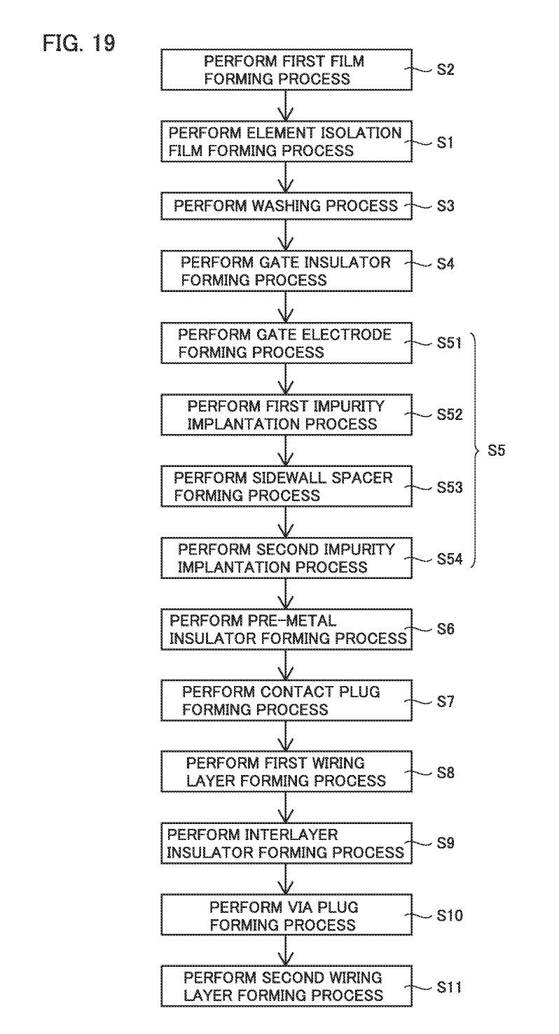

As illustrated in FIG. 19, similarly to the method of manufacturing the semiconductor device of the first embodiment, the method of manufacturing the semiconductor device of the second embodiment includes element isolation film forming process S1, first film forming process S2, cleaning process S3, gate insulator foaming process S4, semiconductor element forming process S5, pre-metal insulator forming process S6, contact plug forming process S7, first wiring layer forming process S8, interlayer insulator forming process S9, via plug forming process S10, and second wiring layer forming process S11.

In the method of manufacturing the semiconductor device of the second embodiment, the order of element isolation film forming process S1 and first film forming process S2 is different from that of the method of manufacturing the semiconductor device of the first embodiment. First film forming process S2 is performed before element isolation film forming process S1.

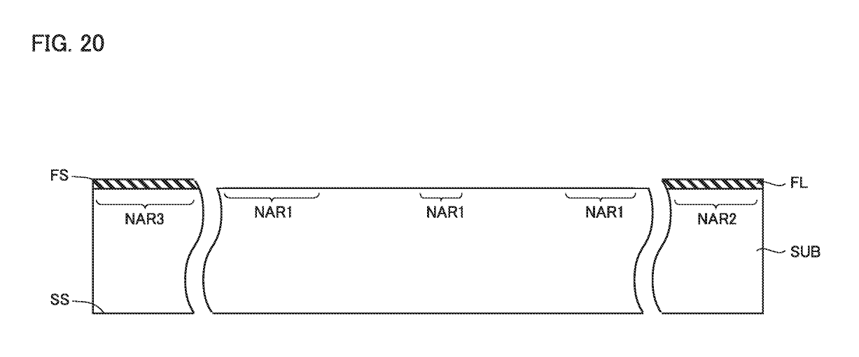

As illustrated in FIG. 20, in first film forming process S2, first film FL is formed on first surface FS of semiconductor substrate SUB located in second region NAR2 and third region NAR3. First film FL is formed by depositing the material constituting first film FL on first surface FS by CVD or the like, and by patterning the material constituting deposited first film FL by photolithography.

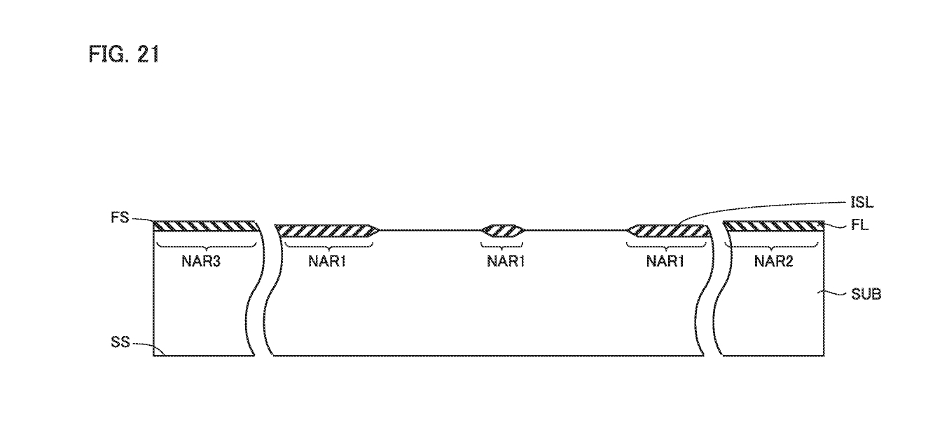

As illustrated in FIG. 21, in element isolation film forming process S1, element isolation film ISL is formed on first surface FS of semiconductor substrate SUB. In the formation of element isolation film ISL, first, a mask is formed on first surface FS of semiconductor substrate SUB. The mask is disposed on first surface FS of the portion in which impurity diffusion region DR is formed. In the formation of element isolation film ISL, second, the thermal oxidation is performed on first surface FS of semiconductor substrate SUB located in the portion in which the mask is not disposed.

As described above, first film FL is already formed on first surface FS located in second region NAR2 and third region NAR3. Consequently, first surface FS located in second region NAR2 and third region NAR3 is not thermally oxidized, and element isolation film ISL is not formed on first surface FS located in second region NAR2 and third region NAR3.

In the semiconductor device manufacturing process, another cleaning process may be performed before cleaning process S3. In the method for manufacturing the semiconductor device of the second embodiment, first film forming process S2 is performed before element isolation film forming process S1. Consequently, the foreign matter generated in another cleaning process performed before cleaning process S3 can also be adsorbed to first film FL. Therefore, in the semiconductor device and the method for manufacturing the semiconductor device of the second embodiment, the occurrence of defect in semiconductor element SE due to the foreign matter can further be prevented.

### Third Embodiment

A configuration of a semiconductor device according to a third embodiment will be described below. In the following description, a point different from the configuration of the semiconductor device of the first embodiment will be mainly described, and the same description will be omitted.

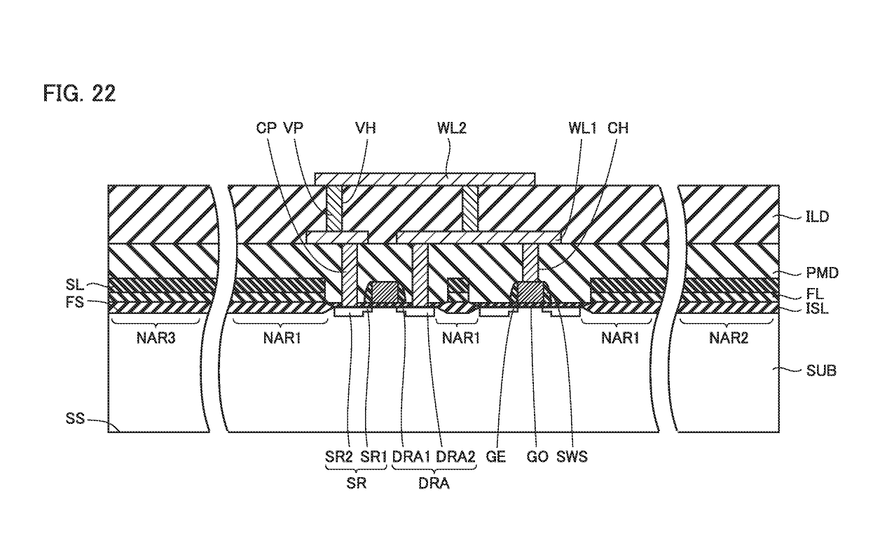

As illustrated in FIG. 22, the semiconductor device of the third embodiment includes semiconductor substrate SUB, gate insulator GO, gate electrode GE, first film FL, element isolation film ISL, sidewall spacer SWS, pre-metal insulator PMD, contact plug CP, wiring layer WL1, interlayer insulator ILD, via plug VP, and wiring layer WL2.

Semiconductor substrate SUB includes first surface FS and second surface SS. Inactive region NAR includes first region NAR1, second region NAR2, and third region NAR3.

Semiconductor substrate SUB includes an impurity diffusion region DR. Impurity diffusion region DR includes a source region SR and a drain region DRA. Source region SR includes a first portion SR1 and a second portion SR2. Drain region DRA includes first portion DRA1 and second portion DRA2.

Source region SR, drain region DRA, gate insulator GO, and gate electrode GE constitute semiconductor element SE. The plurality of semiconductor elements SE are provided. The plurality of semiconductor elements SE constitute the plurality of element blocks CBL. In these respects, the semiconductor device of the third embodiment is the same as the semiconductor device of the first embodiment.

The semiconductor device of the third embodiment is different from the semiconductor device of the first embodiment in that the semiconductor device of the third embodiment further includes a second film SL. Second film SL is disposed on first film FL. That is, second film SL is disposed in inactive region NAR.

Second film SL, is made of the material that is oppositely charged with respect to the material constituting semiconductor substrate SUB in the acid solution. Preferably second film SL is made of the material that is oppositely charged with respect to the material constituting semiconductor substrate SUB in the acid solution having a pH of 4 or less. More preferably second film SL, is made of the material that is oppositely charged with respect to the material constituting semiconductor substrate SUB in the acid solution having a pH of 3 or less.

The material constituting second film SL may be the same material as the material constituting first film FL. The material constituting second film SL is the same material as the material constituting sidewall spacer SWS. Specifically, second film SL and sidewall spacer SWS are made of SiN.

A method for manufacturing the semiconductor device of the third embodiment will be described below. In the following description, a point different from the method of manufacturing the semiconductor device of the first embodiment will mainly be described, and the overlapping description will be omitted.

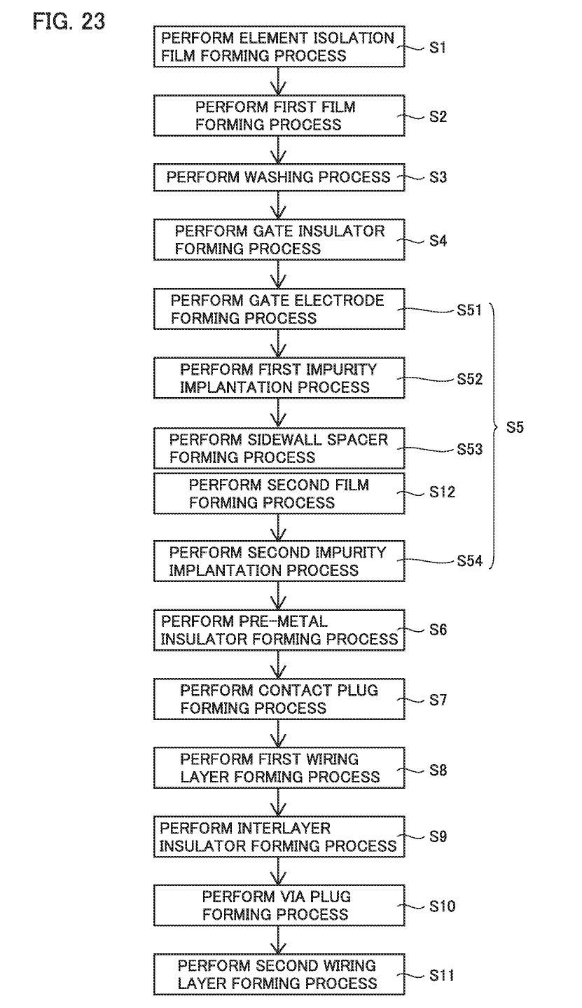

As illustrated in FIG. 23, similarly to the method of manufacturing the semiconductor device of the first embodiment, the method of manufacturing the semiconductor device of the third embodiment includes element isolation film forming process S1, first Film forming process S2, cleaning process S3, gate insulator forming process S4, semiconductor element forming process S5, pre-metal insulator forming process S6, contact plug forming process S7, first wiring layer forming process S8, interlayer insulator forming process S9, via plug forming process S10, and second wiring layer forming process S11.

The method for manufacturing the semiconductor device of the third embodiment further includes a second film forming process S12. In this respect, the method for manufacturing the semiconductor device of the third embodiment is different from the method for manufacturing the semiconductor device of the first embodiment. Second film forming process S12 is performed at the same time as sidewall spacer forming process S53.

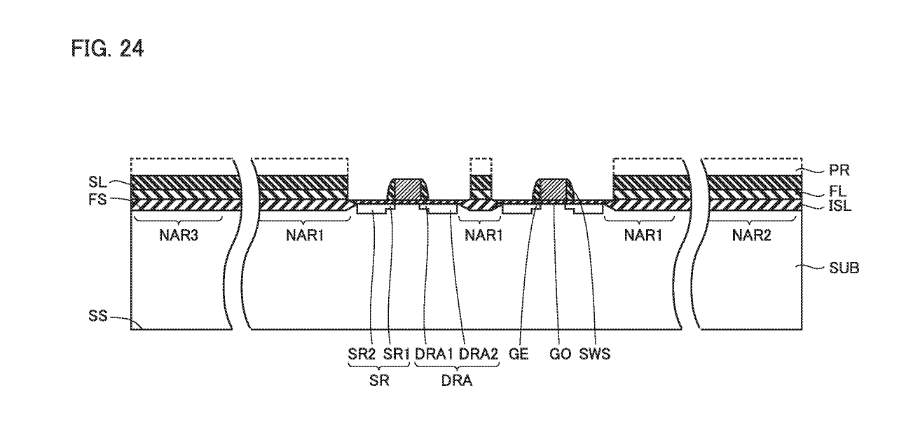

As illustrated in FIG. 24, second film SL and sidewall spacer SWS are simultaneously formed in second film forming process S12 and sidewall spacer forming process S53. In the formation of second film SL and sidewall spacer SWS, first, the material constituting second film SL and sidewall spacer SWS are deposited on gate electrode GE, gate insulator GO, and first film FL by CVD or the like. In the formation of second film SL and sidewall spacer SWS, second, a photoresist PR is formed on second region NAR2 and third region NAR3.

In the formation of second film SL and sidewall spacer SWS, third, the anisotropic etching such as RIE is performed on the material constituting deposited second film SL and sidewall spacer SWS until the upper surface of gate electrode GE is exposed. At this point, because the material constituting second film SL and sidewall spacer SWS, which are deposited on second region NAR2 and third region NAR3, is covered with photoresist PR, the material is left without being etched. As described above, second film SL and sidewall spacer SWS, which are made of the same material, are simultaneously formed.

In the semiconductor device manufacturing process, another cleaning process may be performed even after gate insulator forming process S4. The surface of first film FL is also thermally oxidized in performing gate insulator forming process S4. Consequently, after gate insulator forming process S4, first film FL loses ability to adsorb the foreign matter contained in the cleaning solution.

However, in the semiconductor device and the method for manufacturing the semiconductor device of the third embodiment, second film SL having the ability to adsorb the foreign matter contained in the cleaning solution is newly formed. Consequently, in the semiconductor device and the method for manufacturing the semiconductor device of the third embodiment, the foreign matter contained in the cleaning solution can be prevented from re-adhering in the cleaning process performed after gate insulator forming process S4.

### Fourth Embodiment

A semiconductor device according to a fourth embodiment will be described below. In the following description, a point different from the semiconductor device of the first embodiment will be mainly described, and the same description will be omitted.

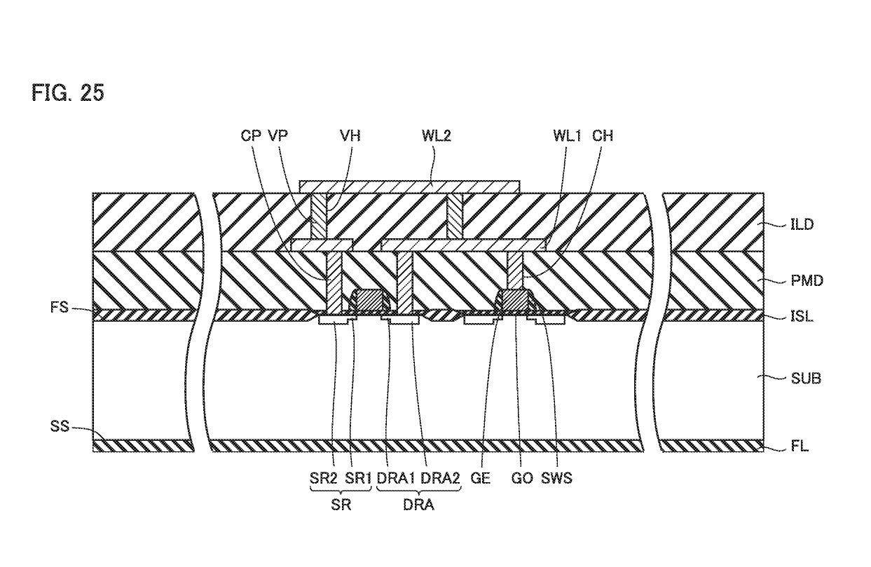

As illustrated in FIG. 25, the semiconductor device of the fourth embodiment includes semiconductor substrate SUB, gate insulator GO, gate electrode GE, first film FL, element isolation film ISL, sidewall spacer SWS, pre-metal insulator PMD, contact plug CP, wiring layer WL1, interlayer insulator ILD, via plug VP, and wiring layer WL2.

Semiconductor substrate SUB includes first surface FS and second surface SS. Semiconductor substrate SUB includes an impurity diffusion region DR. Impurity diffusion region DR includes a source region SR and a drain region DRA. Source region SR includes a first portion SR1 and a second portion SR2. Drain region DRA includes first portion DRA1 and second portion DRA2.

Source region SR, drain region DRA, gate insulator GO, and gate electrode GE constitute semiconductor element SE. The plurality of semiconductor elements SE are provided. The plurality of semiconductor elements SE constitute the plurality of element blocks CBL. In these respects, the semiconductor device of the fourth embodiment is the same as the semiconductor device of the first embodiment.

In the semiconductor device of the fourth embodiment, first film FL is formed on second surface SS. In this respect, the semiconductor device of the fourth embodiment is different from the semiconductor device of the first embodiment.

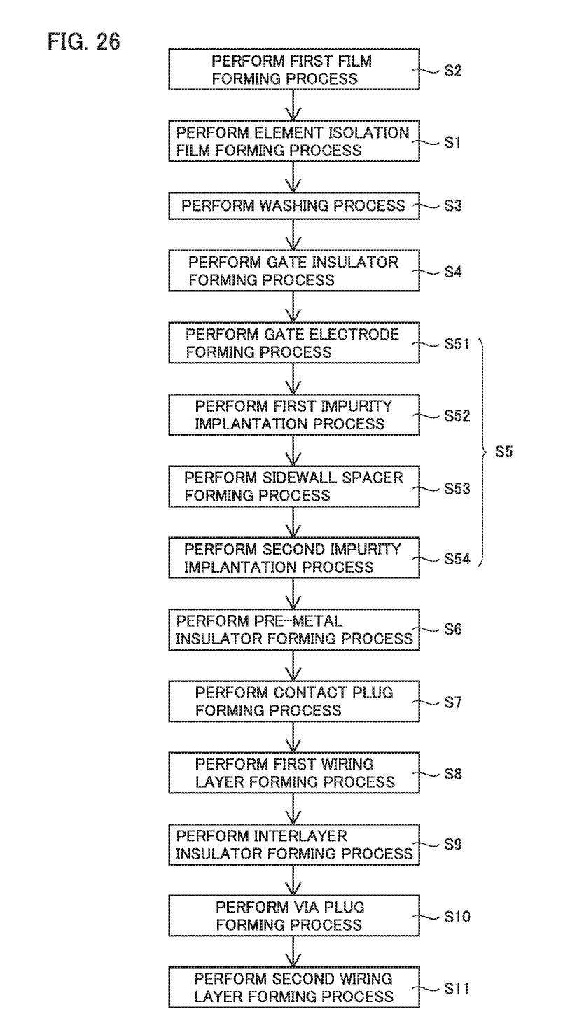

As illustrated in FIG. 26, similarly to the method of manufacturing the semiconductor device of the first embodiment, the method of manufacturing the semiconductor device of the fourth embodiment includes element isolation film forming process S1, first film forming process S2, cleaning process S3, gate insulator forming process S4, semiconductor element forming process S5, pre-metal insulator forming process S6, contact plug forming process S7, first wiring layer forming process S8, interlayer insulator forming process S9, via plug forming process S10, and second wiring layer forming process S11.

The semiconductor device manufacturing method of the fourth embodiment is different from the semiconductor device manufacturing method of the first embodiment in that first film forming process S2 is performed before element isolation film forming process S1.

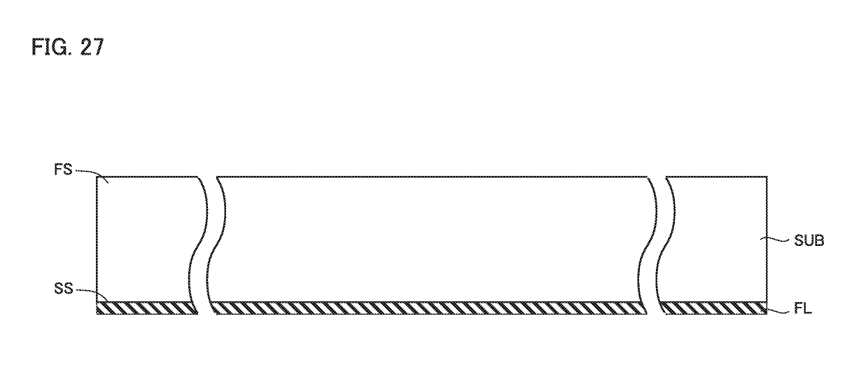

As illustrated in FIG. 27, in first film forming process S2 of the semiconductor device manufacturing method of the fourth embodiment, first film FL is formed on second surface SS of semiconductor substrate SUB. For example, first film FL is formed by depositing the material constituting first film FL by CVD or the like.

Semiconductor element SE is not formed on the side of second surface SS of semiconductor substrate SUB. For this reason, in the semiconductor device of the fourth embodiment, first film FL does not have an influence on the formation of semiconductor element SE. Consequently, in the semiconductor device and the method for manufacturing the semiconductor device of the fourth embodiment, the influence on the formation of semiconductor element SE due to the formation of first film FL can further be prevented.

Although not described in the embodiments of the present invention, it should be considered that the disclosed embodiments are an example in all respects and not restrictive. The scope of the present invention is indicated by the claims, and it is intended that all modifications within the meaning and scope of the claims are included in the present invention.

What is claimed is:

1. A semiconductor device manufacturing method comprising the steps of:
forming a gate insulator on a surface of a semiconductor substrate;
forming at least one semiconductor element on the surface of the semiconductor substrate, the semiconductor element including a source region, a drain region, and a gate electrode that faces a portion of the semiconductor substrate with the gate insulator interposed therebetween, the portion sandwiched between the source region and the drain region;
forming a first film on the surface of the semiconductor substrate; and
cleaning the semiconductor substrate using an acid solution,
wherein
the first film is made of a material that is oppositely charged with respect to a material constituting the semiconductor substrate in the acid solution,
the step of forming the first film is performed before the step of forming the gate insulator, and
the first film is formed so as to be located in an inactive region that does not overlap a portion in which the source region is formed, a portion in which the drain region is formed, and a portion in which the gate electrode is formed in plan view.

2. The semiconductor device manufacturing method according to claim 1, wherein the first film is made of the material that is oppositely charged with respect to the material constituting the semiconductor substrate in the acid solution having a pH of 4 or less.

3. The semiconductor device manufacturing method according to claim 1, wherein
the material constituting the semiconductor substrate is silicon, and
the material constituting the first film is silicon nitride.

4. The semiconductor device manufacturing method according to claim 1, wherein
in the step of forming the semiconductor element, the semiconductor element comprising a plurality of semiconductor elements is formed,
the plurality of semiconductor elements constitute a plurality of element blocks that are disposed while separated from each other in plan view, and
the first film is disposed in the inactive region located inside each of the plurality of element blocks in plan view.

5. The semiconductor device manufacturing method according to claim 1, wherein
in the step of forming the semiconductor element, the semiconductor element comprising a plurality of semiconductor elements is formed,
the plurality of semiconductor elements constitute a plurality of element blocks that are disposed while separated from each other in plan view, and
the first film is disposed in the inactive region located between the element blocks adjacent to each other in plan view.

6. The semiconductor device manufacturing method according to claim 1, wherein
in the step of forming the semiconductor element, the semiconductor element comprising a plurality of semiconductor elements is formed,
the plurality of semiconductor elements constitute a plurality of element blocks that are disposed while separated from each other in plan view, and
the first film is disposed in the inactive region located outside of the element block disposed on an outermost side in the plurality of element blocks in plan view.

7. The semiconductor device manufacturing method according to claim 1, further comprising:
the step of forming an element isolation film insulating and isolating the semiconductor element, wherein
the step of forming the first film is performed before the step of forming the element isolation film.

8. The semiconductor device manufacturing method according to claim 1, further comprising:
the step of forming a second film made of a material that is oppositely charged with respect to the material constituting the semiconductor substrate in the acid solution on the first film,
wherein
the step of forming the semiconductor element includes the step of forming a sidewall spacer disposed on a lateral side of the gate electrode,
the second film and the sidewall spacer are made of the same material, and
the step of forming the second film is performed at the same time as the step of forming the sidewall spacer.

9. A semiconductor device comprising:
a semiconductor substrate including a surface, a source region disposed in contact with the surface, and a drain region that is disposed in contact with the surface while separated from the source region;
a gate electrode that faces a portion of the semiconductor substrate sandwiched between the source region and the drain region while being insulated from the portion of the semiconductor substrate in the surface;
a semiconductor element constructed with the source region, the drain region, and the gate electrode; and
a first film that is disposed on the surface and made of a material that is oppositely charged with respect to the material constituting the semiconductor substrate in an acid solution,
wherein
the first film is located in an inactive region that does not overlap the source region, the drain region, and the gate electrode in plan view.

10. The semiconductor device according to claim 9, wherein
the semiconductor element comprises a plurality of semiconductor elements,
the plurality of semiconductor elements constitute an element block, and
the first film is located in the inactive region located inside the element block in plan view.

11. The semiconductor device according to claim 9, wherein
the semiconductor element comprises a plurality of semiconductor elements,
the plurality of semiconductor elements constitute a plurality of element blocks that are disposed while separated from each other in plan view, and
the first film is located in the inactive region located outside the plurality of element blocks adjacent to each other in plan view.

12. The semiconductor device according to claim 9, wherein
the semiconductor element comprises a plurality of semiconductor elements,
the plurality of semiconductor elements constitute a plurality of element blocks that are disposed while separated from each other in plan view, and
the first film is located in the inactive region located outside the plurality of element blocks in plan view.

13. The semiconductor device according to claim 9, further comprising:
an element isolation film insulating and isolating the semiconductor element on the surface,
wherein
the first film is disposed in contact with the surface so as not to overlap the element isolation film in plan view.

14. The semiconductor device according to claim 9, further comprising:
a second film that is disposed on the first film and made of a material oppositely charged with respect to the material constituting the semiconductor substrate in the acid solution, and
a sidewall spacer disposed on a lateral side of the gate electrode,
wherein
the second film and the sidewall spacer are made of the same material.
